(19) United States
(12) Patent Application Publication
(10) Pub. No.: US 2008/0179666 A1
(43) Pub. Date: Jul. 31, 2008

(54) SEMICONDUCTOR DEVICE HAVING A TRENCH GATE AND METHOD FOR MANUFACTURING

(75) Inventors: Christian Foerster, Villach (AT); Georg Ehrentraut, Villach (AT); Frank Pfirsch, Muenchen (DE); Thomas Raker, Ottobrunn (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: INFINEON TECHNOLOGIES AG, Neubiberg (DE)

(21) Appl. No.: 12/019,295

(22) Filed: Jan. 24, 2008

(30) Foreign Application Priority Data
Jan. 25, 2007 (DE) 10 2007 003 812.9

(51) Int. Cl. H01L 29/78; H01L 21/336

(52) U.S. Cl. 257/330; 438/270; 257/E29.257

(57) ABSTRACT

A semiconductor device having a trench gate and method for manufacturing is disclosed. One embodiment includes a first semiconductor area and a second semiconductor area, a semiconductor body area between the first semiconductor area and the second semiconductor area, and a gate arranged in a trench and separated from the semiconductor body by an insulation layer, wherein the trench has a top trench portion which extends from the semiconductor surface at least to a depth which is greater than a depth of the first semiconductor area, wherein the trench further has a bottom trench portion extending subsequent to the top trench portion at least up to the second semiconductor area, and wherein the top trench portion has a first lateral dimension and the bottom trench portion has a second lateral dimension which is greater than the first lateral dimension.

### CROSS-REFERENCE TO RELATED APPLICATIONS

This Utility Patent Application claims priority to German Patent Application No. DE 10 2007 003 812.9 filed on Jan. 25, 2007, which is incorporated herein by reference.

### BACKGROUND

The present invention relates to semiconductor devices and in one embodiment to MOSFETs or power MOSFETs having a trench gate and to bipolar transistors having an insulated gate which are also known as IGBTs (insulated gate bipolar transistor).

Power MOSFETs may basically be realized in two different designs. In current standard devices the channel is implemented horizontally at the surface of a semiconductor material, also designated as planar MOS field-effect transistors. There is also a vertical design of power transistors, wherein the channel extends along the edge of a trench structure etched into the semiconductor material, and thus the source-drain current flows perpendicular to the wafer surface. The power MOSFETs realized in the trench design, i.e. having a vertically implemented channel, have the advantage that the channel width is clearly increased and thus the on resistance may be reduced. Thus, an enormous scaling potential as compared to the planar design results.

Bipolar transistors having an insulated gate also exist both as a planar variant and also as a non-planar variant. The non-planar variants in which the channel area is formed along a vertical trench edge have the advantage compared to planar structures in which the channel is implemented at the top side of the substrate that the achieved forward voltages V_{CESat} become lower. The reason for this is that the charge carrier density at the cathode or emitter side end, respectively, of the low-doped central area may become substantially higher than with a planar IGBT. This is because a low forward voltage is achieved when the charge carrier concentration of the IGBT in the ON state is very similar to the charge carrier concentration of a PIN diode. This means, that both on the anode and collector side, respectively, and also on the cathode or emitter side, respectively, a high charge carrier concentration is present. On the other hand, with trench IGBTs the case may arise in which the charge carrier concentration strongly decreases towards the emitter-side end compared to the charge carrier concentration at the collector-side end.

For these and other reasons, there is a need for the present invention.

### SUMMARY

One embodiment provides a semiconductor device having a first semiconductor area and a second semiconductor area, a semiconductor body area between the first semiconductor area and the second semiconductor area, wherein a doping characteristic of the semiconductor body area is inverse to a doping characteristic of the first semiconductor area and the second semiconductor area, a trench which extends adjacent to the semiconductor body area from the semiconductor surface at least up to the second semiconductor area, a gate arranged in the trench, separated from the semiconductor body by an insulation layer, wherein the trench includes a top trench portion extending from the semiconductor surface at least to a depth which is greater than a depth of the first semiconductor area, wherein the trench further includes a bottom trench portion which extends subsequent to the top trench portion at least up to the second semiconductor area, and wherein the top trench portion has a first lateral dimension and the bottom trench portion has a second lateral dimension which is greater than the first lateral dimension.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1A illustrates a bipolar transistor having an insulated gate according to one embodiment.

FIG. 1B illustrates a field-effect transistor having a trench gate according to one embodiment.

FIG. 1C illustrates a semiconductor device having two adjacent trenches.

FIG. 2A illustrates different variants A, B, C, D of an insulated trench compared to an insulated trench of a reference structure and associated doping distributions.

FIG. 2B illustrates different parameters of the variants of FIG. 2A.

FIG. 2C illustrates charge carrier concentrations for the variants of FIG. 2A in a vertical section through the device.

FIG. 3 illustrates a principle illustration for the method for manufacturing a bipolar transistor having an insulated gate.

FIG. 4 illustrates an embodiment having two spaced-apart trenches.

FIG. 5 illustrates a further embodiment having three trenches.

FIG. 6 illustrates a schematical view of a trench form.

FIG. 7 illustrates microscopic recordings of etched trenches.

FIG. 8 illustrates field-strength simulations of the trench according to one embodiment compared to a standard trench.

FIG. 9 illustrates an illustration of the breakthrough characteristic curve for the standard trench and a trench according to one embodiment.

FIG. 10 illustrates an illustration of a field-strength course in the oxide for a standard trench and a trench according to one embodiment.

FIG. 11A illustrates a principle illustration of the method processes for manufacturing an MOSFET as an example for a semiconductor device having a trench without spreading.

FIG. 11B illustrates a principle illustration of the method processes for manufacturing an MOSFET as an example for a semiconductor device having a trench with spreading.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

One embodiment provides a semiconductor device having a first semiconductor area and a second semiconductor area, a semiconductor body area between the first semiconductor area and the second semiconductor area, wherein a doping characteristic of the semiconductor body area is inverse to a doping characteristic of the first semiconductor area and the second semiconductor area, a trench which extends adjacent to the semiconductor body area from the semiconductor surface at least up to the second semiconductor area, a gate arranged in the trench, separated from the semiconductor body by an insulation layer, wherein the trench includes a top trench portion extending from the semiconductor surface at least to a depth which is greater than a depth of the first semiconductor area, wherein the trench further includes a bottom trench portion which extends subsequent to the top trench portion at least up to the second semiconductor area, and wherein the top trench portion has a first lateral dimension and the bottom trench portion has a second lateral dimension which is greater than the first lateral dimension.

One or more embodiments include a bipolar transistor having an insulated gate with an emitter and a collector, a base area between the emitter and the collector which is separated into a top base area or body area, respectively, of one conduction type and a bottom base area of the other conduction type, and a trench which extends through the emitter and the top base area into the bottom base area, wherein the trench is filled with a conductive material and is insulated from the base area and the emitter, and wherein the trench has a first lateral dimension d₁ in its top portion and a second lateral dimension d₂ which is greater than the first dimension in its bottom portion extending into the bottom base area.

One or more embodiments include a (power) MOSFET having an insulated gate with a source area and a drain area which may be separated in a top low-doped drift distance area and a bottom high-doped drain terminal area; a body area between the source area and the drain area; and a trench extending through the source area and the body area into the drain area, wherein the trench is at least partially filled with a conductive material and is insulated from the body area and the source area, and wherein the trench includes a first lateral dimension d₁ in its top portion and a second lateral dimension d₂ which is greater than the first dimension in its bottom portion extending into the drain area.

One or more embodiments include methods for manufacturing a (power) MOSFET or a bipolar transistor having an insulated gate, including the processes of generating a trench extending into a semiconductor substrate which includes a spreading in the semiconductor substrate so that the trench is wider in one area of the spreading than in an area adjacent to the spreading; generating an insulation layer in the trench; filling the trench with a conductive material; and generating a source or emitter terminal, respectively, contacting a source area or an emitter area, respectively, and a drain or collector terminal, respectively, contacting a drain area or a collector area, respectively, wherein the trench extends through a body area and into the drain area or the bottom base area, respectively, and wherein at least one portion of the spreading is arranged outside the body area.

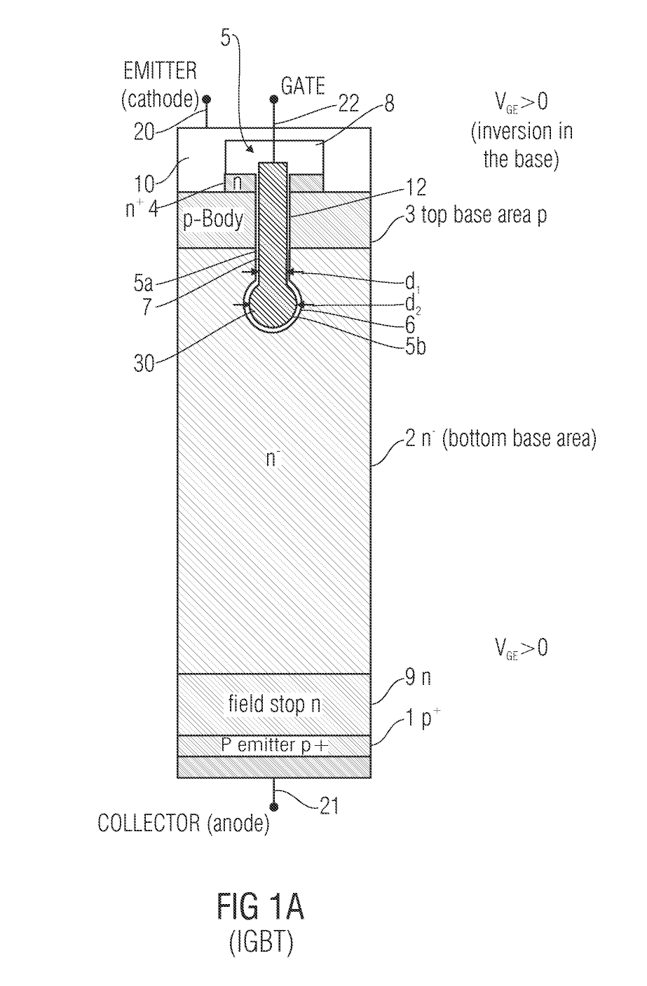

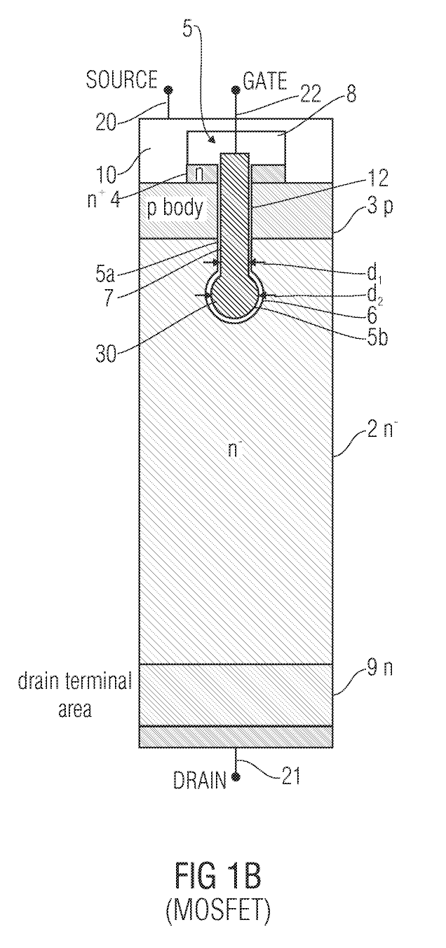

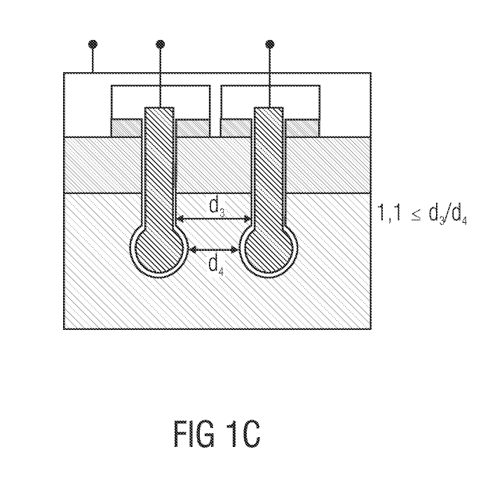

Before the figures are discussed in more detail, it is to be noted that FIG. 1a only illustrates one embodiment of the inventive semiconductor device which is implemented as a bipolar transistor having an insulated gate (IGBT). FIG. 1b also illustrates one embodiment of the inventive semiconductor device implemented as an MOSFET. Although the two transistor types are effectively different, regarding the implementations illustrated in FIG. 1a and FIG. 1b they are only different by the fact that the p-emitter 1 which represents the collector of the bipolar transistor of FIG. 1a is not present in the MOSFET field-effect transistor of FIG. 1b.

In general, the semiconductor device includes a first semiconductor area 4 and a second semiconductor area 2. The first semiconductor area 4 is e.g., the source area in the IGBT of FIG. 1a which is connected to the emitter contact 5, while the second semiconductor area 2 in the IGBT of FIG. 1a is designated as the n-base area or the bottom base area and the semiconductor body area 3 represents the top base area. The p-emitter, i.e. layer 1, is connected to the collector terminal 21.

In any case, between the first semiconductor area 4 and the second semiconductor area 2 a semiconductor body area 3 is arranged which is designated also as the p-base area or top base area in the IGBT, while it might also be referred to as the “bulk” area in the MOSFET, namely as the area of the MOSFET in which the conductive channel may be formed.

Both in the IGBT and also in the MOSFET the doping characteristics of the semiconductor body area on the one hand and the first and the second semiconductor areas 4, 2 are inverse.

The trench 5 extends adjacent to the semiconductor body area from the semiconductor surface at least to the second semiconductor area 2, i.e. into the low-doped layer. As it may be seen from FIG. 1a or FIG. 1b, the trench includes a top trench portion 5a and a bottom trench portion 5b, wherein the lateral dimension d2 of the bottom trench portion is greater than the lateral dimension d1 of the top trench portion. The semiconductor element indicated in cross-section in FIG. 1a or FIG. 1b typically includes a first main surface and a second main surface and the trench will, for example, extend vertically into the device. In general, the trench will have a direction such that its longitudinal axis intersects both the first main surface where the emitter contact is located, and also the second main surface where the collector contact is located. The lateral dimension is a dimension of the trench in a direction which is different from the longitudinal direction of the trench, i.e. the “extending direction” of the trench into the semiconductor device.

At this point it is to be noted that the trench, if the semiconductor device is regarded from the top, includes a longitudinal form which has a direction which has a directional component which is parallel to the surface of the semiconductor device. This directional component is typically perpendicular to the longitudinal extension of the trench into the device and also perpendicular to the lateral dimension of the trench which is the lateral dimension which is smaller in the top area of the trench than in the bottom area of the trench.

It is to be noted that the bottom area of the trench does not necessarily have to be the trench bottom. Instead, the advantages may also be achieved if the trench had a further slim portion which extended further into the layer 2 subsequent to the bottom trench portion. For manufacturing reasons it may be advantageous, however, to implement the spreading or the bottom trench portion, respectively, which has a higher lateral dimension, identical to the trench bottom.

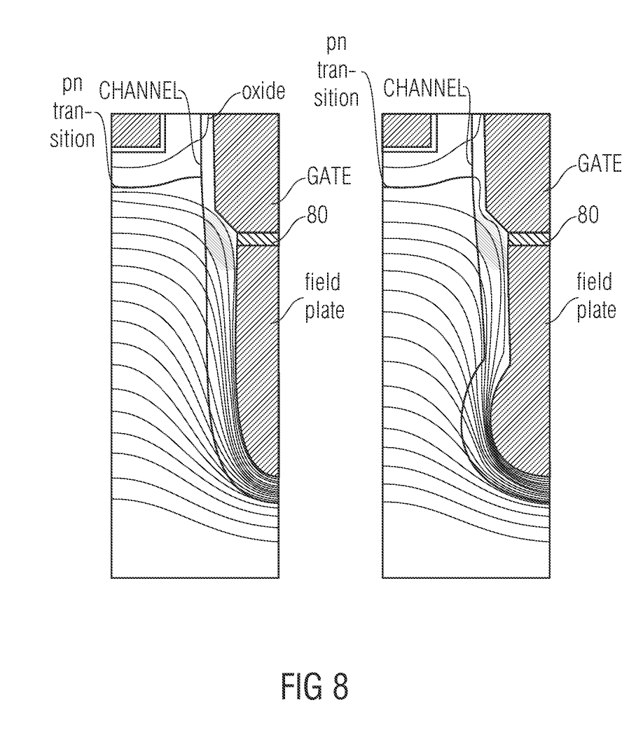

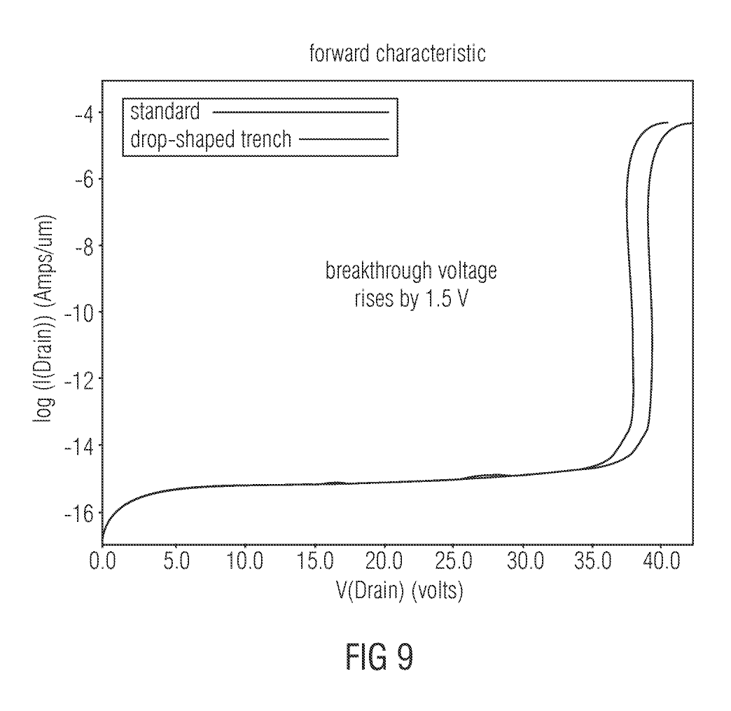

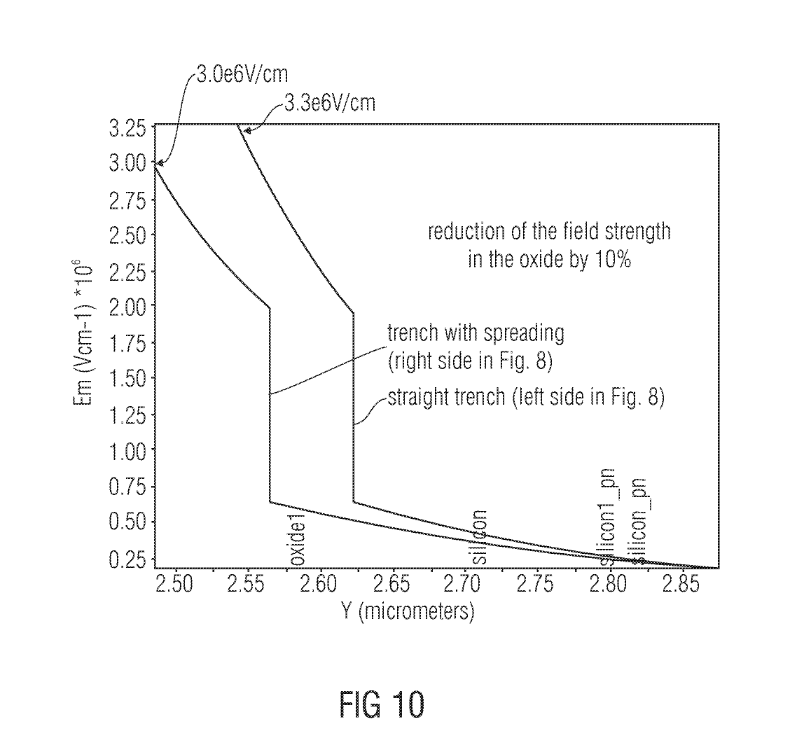

At this point reference is already made to FIG. 8 which illustrates an alternative implementation for the “trench filling”. Thus, the trench has a bottom filling portion which is designated as “field plate”. This bottom filling portion is, just like the top filling portion, which forms the actual gate, insulated from the semiconductor material by an oxide. However, there may also be an insulation 80 between the gate and the field plate, i.e. between the two filling portions. The field plate may, in this case, be implemented floatingly, i.e. so that it has no potential terminal and its potential sets to a certain value by itself. In one embodiment, the field plate is accessible, however, for example at the edge of the transistor, e.g., to be contacted through contact holes. In a wiring plane these contact holes are then e.g., short-circuited with the source metallization or emitter metallization 10, respectively, so that the field plane is on the same potential as the source or the emitter, respectively. A detailed description of the field plate effect may be found in the U.S. Pat. No. 4,941,026. In one embodiment, the field plate is used so that with the same breakdown (breakthrough) voltage a lower forward resistance or with the same forward resistance higher breakdown voltages may be achieved.

FIG. 1a illustrates a bipolar transistor having an insulated gate, wherein the bipolar transistor includes an emitter and a collector. The emitter includes an emitter terminal 20 which is conductively connected to an n+-area 4. The n+-area of the emitter abuts on a p-base area or a body area 3 or to a top base area, respectively. The p-base area 3 is arranged on a low-doped n−-layer 2 or n−-base 2, respectively, also referred to as the bottom base area, which is in turn arranged on a field stop layer or buffer layer 9, wherein the buffer layer 9 is higher n-doped than the n−-layer 2, as it is illustrated by n. Typically, the area 4 is higher doped than the area 9, however. On the field stop layer 9 a p+-layer 1 is arranged which is represented as a p-emitter, as this layer emits holes, however represents the collector of the bipolar transistor regarding the original bipolar transistor notation. The collector of the bipolar transistor is connected to a collector terminal 21 which is, for example, made of metal. A gate electrode 7 extends through the p-base layer 3 and into the low-doped n-layer 2 and is implemented in a trench 5, wherein the gate electrode is insulated from the surrounding area by an oxide layer 6. The oxide layer 6 is further also attached above the trench at 8 for insulation. The gate electrode 7 is connected to a gate terminal 22.

In one embodiment, the semiconductor device may also be a power transistor or a power MOSFET, respectively, indicated in FIG. 1b. In this case, the p+-layer 1 is replaced by an n+-layer or an n+-substrate, respectively. The field stop layer 9 may also be omitted. Further, the doping characteristics may be selected inversely.

In one embodiment, the MOS field-effect transistor indicated in FIG. 1b is a transistor having a vertical channel. The channel extends in the semiconductor body area 3 which is p-doped in the embodiment illustrated in FIG. 1b. The first semiconductor area 4 then acts as a source area and the second semiconductor area 2 acts as a drain area, while the channel forms in the body area which is an inversion channel in the embodiment illustrated in FIG. 1b, as the MOSFET illustrated in FIG. 1b is a self-locking transistor.

In one embodiment, the trench 5 includes a spreading 30 in the bottom part of the trench in which the trench is wider than in the top part, i.e. where the reference numeral 7 is located. The trench thus includes a spreading section at the reference numeral 30 and a longitudinal trench portion above the spreading section 30. In general, the trench is dimensioned such that the trench represents a barrier for free charge carriers moving past the trench in the direction of the base area.

In order to illustrate this in more detail, first reference is made to the functionality of the IGBT.

If a certain collector voltage VCE is applied between the emitter electrode 20 and the collector electrode 21 which is higher than 0 with the doping ratios illustrated in FIG. 1a and which is smaller than 0 if the doping ratios are exactly inverse, and if further a certain gate voltage VGE is applied between the emitter electrode 20 and the gate electrode 22, which is also positive with the doping ratios illustrated in FIG. 1a, and which would, however, be negative with inverse doping ratios, i.e. when the gate is “switched on”, then an inversion layer is generated in the base layer designated by the reference numeral 12. This means, that in the p-base 3 a channel of the n-type is formed. Further, based on the voltage VCE, electrons are injected from the emitter electrode, i.e. from the n+-area 4, through the channel in the inversion area 12 into the low n-doped layer 2. The injected electrons thus achieve a flow polarity between the p+-collector layer 1 And the n+-buffer layer 9. The p+-collector layer 1 thus emits holes into the n−-layer 2. As a result, the resistance of the n−-layer 2 decreases, that is due to a conductivity change due to the many injected charge carriers. Thus, also the current capacity of the IGBT increases. The voltage decrease between the collector and the emitter of the IGBT is then the ON voltage, also designated as VCEsat.

If the IGBT is brought from an ON state into an OFF state, i.e. when the voltage VGE between the emitter electrode 20 and the gate electrode 22 is brought to 0 volts or becomes negative, i.e. when the gate is switched off, then the inversion of the channel region 12 is undone. The electron injection of the emitter electrode (terminal 20 and strongly doped area 4) ends. Apart from that, electrons and holes stored in the n−-layer flow towards the collector electrode or the emitter electrode, respectively, or the charge carriers recombine.

In general, the ON voltage of the IGBT is to a substantial extent determined by the resistance of the n−-layer 2 whose thickness and doping is dimensioned such that the necessitated breakdown voltage is achieved. This resistance mainly depends on the degree of charge carrier flooding, i.e. the number of free charge carriers in the layer 2. The more electrons and holes are present in the layer, the lower the resistance.

In a PIN diode used for comparison which has a low ON resistance and which simultaneously has a high breakdown voltage, the charge carrier distribution between p and n, i.e. in the i-zone, is relatively constant. In an IGBT, if a standard trench were present which did not have the spreading 30, i.e. which is not implemented such that it presents a barrier for holes when they move towards the emitter, the distribution of the free charge carriers in the n−-area would be such that at the collector-side end, i.e. at the bottom of FIG. 1a, many free charge carriers are present, while at the emitter-side end relatively few charge carriers are present. The charge carriers there are to a certain extent holes which flow to the emitter contact. These holes come from the collector, also designated as p-emitter 1 in FIG. 1a, and are injected from there into the n−-area 2 and move past the channel through the base to the emitter.

As will be discussed, the inventive spreading of the trench indicated at 30 causes, so to speak, a “hole jam” to occur at the cathode-side end of the IGBT and in one embodiment at the cathode-side end of the low-doped middle area 2 such that the charge carrier density is increased below this point in the n-layer.

In one or more embodiments, this “hole barrier” is obtained by the fact that the trench is spread at its bottom, i.e. at least in an area which extends into the layer 2.

While the spreading 30 in the bipolar transistor having an insulated gate illustrated in FIG. 1a has an especially favorable effect when the transistor is operated in its conductive state, i.e. when the resistance between the emitter and the collector is low, the spreading 30 in the field-effect transistor illustrated in FIG. 1b has an especially favorable effect when the transistor is operated in reverse direction (non-conducting direction), i.e. when the resistance between drain and source is high, i.e. when no conductive channel exists drain and source.

FIG. 8 illustrates an illustration of a gate section of such an MOSFET in the case of blocking, wherein in one embodiment an implementation with a field plate section in the gate is illustrated, as already discussed above. Thus, FIG. 8 illustrates the course of the equipotential lines around the trench for the case without spreading (left in FIG. 8) and for the case with spreading (right in FIG. 8), wherein the density of the equipotential lines is especially high in the oxide, which is true both in the case with spreading and also for the case without spreading. The density of the equipotential lines which is proportional to the local field strength decreases with an increasing distance from the oxide. It is obvious, however, that in the example without spreading the equipotential lines are especially packed or dense at the peak of the trench, while the equipotential lines in one embodiment with spreading are not so strongly packed. This means that the local field strength in the oxide when spreading is used compared to the case without spreading is reduced, as it is illustrated in FIG. 10. By the spreading, the equipotential lines which are perpendicular on the field lines, which are in turn perpendicular on a metal, are “pressed apart” by the spreading, which explains the reduction of the local field strength in the oxide.

In the embodiment illustrated in FIG. 8, it may in one embodiment be seen that the critical location is the trench peak or the trench bottom, respectively, which is the further apart from the channel area the deeper the trench extends into the layer 2, wherein it is not decisive for the positive effect of the spreading on the field strength in the oxide whether the bottom filling of the trench is conductively connected to the gate electrode or is insulated from the top filling of the trench which represents the gate electrode.

The embodiment illustrated in FIG. 1a further distinguishes itself by the fact that it is a robust device with reference to the overcurrent shutdown. For this purpose the hole current may flow through the body areas to the emitter contact with a current density which is not too high. Then, the voltage drop between source and body area remains sufficiently low, so that the parasitic thyristor of n-source 4, p-body 3, n-base 2 and p-emitter 1 cannot switch on.

The shape of the trench as it is illustrated as an example in FIG. 1a, i.e. that the trench has a spreading which is either completely or at least partially implemented in the n−-layer 2, makes a current path which is as narrow as possible available for the holes and thus improves the hole jam on the front side of the IGBT. The result of this measure is a reduced forward voltage VCEsat which directly presents a reduced ON resistance of the device.

One or more embodiment may be used in embodiments having IGBT strip cells having an n-channel on both sides, wherein with such strip cells active cells are arranged on both sides of the trench, as this variant without trench spreading has a relatively high value for VCEsat.

As it may be seen with reference to the example in FIG. 1a, the trench 5 in the base area 3 has a first lateral dimension d1 which is smaller than a second lateral dimension d2 which the trench has in an area in which it extends into the low-doped layer 2. In one or more embodiments, the second dimension is at least 10% and at least 50% larger than the first dimension. In one embodiment illustrated in FIG. 1a, the ratio of dimensions is even higher than 2 in favor of the spreading area 30.

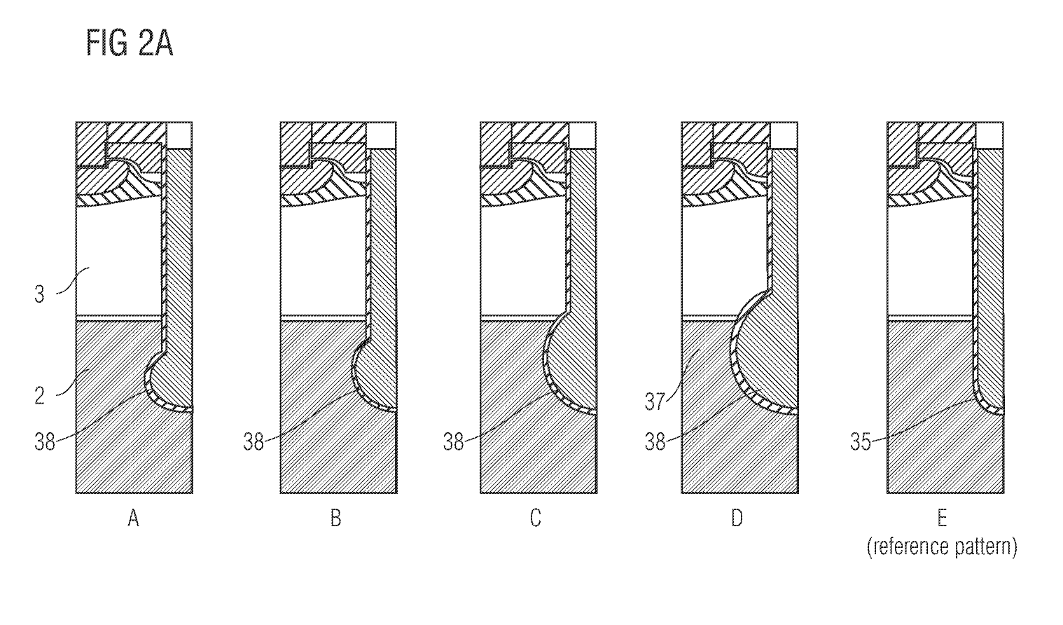

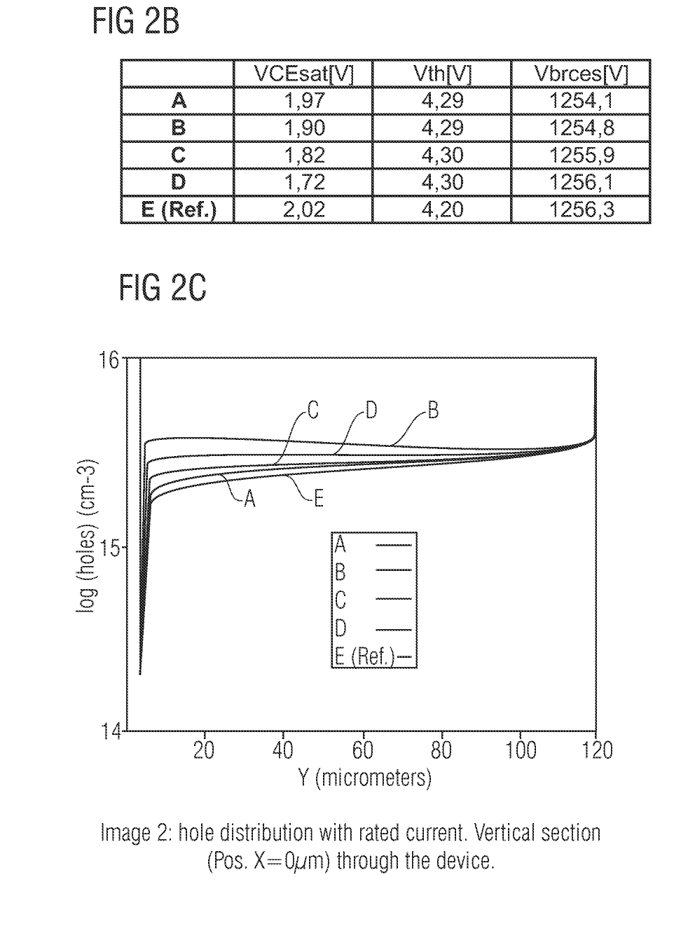

In the following, with reference to FIG. 2a, different variants A, B, C, D are illustrated which differ regarding the size of the spreading 30. Thus, FIG. 2a, for example, illustrates the left half of the illustration of FIG. 1a, that is in the area of interest between the emitter and the low-doped layer 2. Variant E illustrates a reference area in which a conventional “straight” trench is introduced which is tapered to the bottom. On a level with trench bottom edge, i.e. at 35 in FIG. 2E, in the conducting state of the IGBT the hole density is relatively low. However, at 38 the hole density in Figures A, B, C, D is higher than in variant E. The hole concentration in the area of the trench bottom edge and thus also the charge carrier concentration in the area of the n−-layer 2 steadily increases the greater the spreading or the narrower the current path still available between the trenches for the holes, i.e. the greater the spreading radius. The hole jam thus steadily increases with an increasing spreading.

FIG. 2B illustrates the results of a simulation of typical static parameters, like, for example, forward voltage VCEsat, initial voltage Vth and breakdown voltage Vbrces of the cell variants A to E, wherein the examples in FIGS. 2A, 2B, 2C refer to a 1200 V-IGBT. The VCEsat trend reflects the charge carrier jam (reference numeral 38 in FIG. 2A) which gets stronger with an increasing spreading radius. The structure having the greatest radius has the best carrier jam and thus the lowest VCEsat, while the other parameters remain unchanged.

FIG. 2C illustrates, in a vertical section through the device, the hole concentration for the variants A to E in the conductive state. With variant D, i.e. the structure having the greatest spreading radius, a hole concentration about twice as high as with the reference structure E is achieved.

FIG. 2A illustrates embodiments in an illustration as a half-cell structure, wherein the structures which were used for the simulation illustrated in FIG. 2B include mirror planes on the left and right. Further, these are embodiments of a strip cell design and an n-channel type. The structures A, B, C, D are different from the reference structure E by a cylindrically spread end of the gate electrode, wherein the spreading, as it was explained with reference to FIG. 1a at 30, has an approximately circular cross-section. Such cells plotted in FIG. 2A may be arranged next to each other in a high number to provide an IGBT having a higher current capacity.

As it will be discussed in the following, the trench geometry may be generated via a modified trench etching process (e.g., using an oxide spacer). Thus, for example, after the trench etching an oxide may be applied which is subsequently etched back anisotropically. By this, the trench bottom may be freed from the oxide, while at the trench side walls the oxide is still present. In a next process, an isotropic Si etching may be performed which subsequently provides the cylindrical or in, cross-section, circular geometry, respectively, at the trench bottom. This special shape of the trench makes a current path available for the holes which is as narrow as possible and thus improves the hole jam at the front side of the IGBT. The result of this measure is a reduced forward voltage VCEsat.

According to one embodiment, with the help of a design of the gate electrode which is approximately circular in cross-section, the congestion of the charge carriers is achieved to thus achieve a high charge carrier density at the emitter-side end of the IGBT of FIG. 1a. By this, the voltage VCEsat may be substantially reduced compared to the reference structure. All further static parameters, like, for example, Vbrces or Vth, should change as little as possible here. The VCEsat trend reflects the hole jam (congestion) getting stronger due to increasing spreading radius. The structure having the greatest radius has the best carrier jam and thus the smallest VCEsat. The cross-section of the spreading may also include a shape other than the circular shape, for example an elliptical or less regular form.

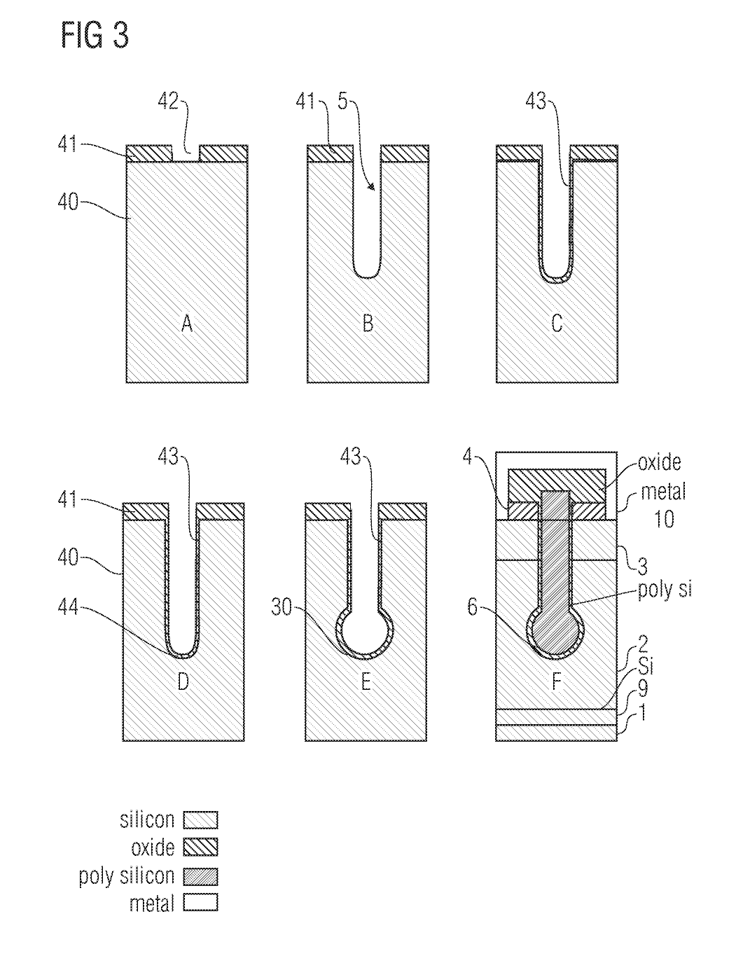

In the following, with reference to FIG. 3, one embodiment of a method for manufacturing an MOSFET or a bipolar transistor having an insulated gate is described. A semiconductor substrate is used as a basis as it is illustrated at A in FIG. 3. The semiconductor substrate 40 illustrated in FIG. 3 is a silicon semiconductor substrate which may already contain different doping areas, for example a drain terminal area and a drift distance area. On this semiconductor substrate a first layer is applied which is an oxide 41. The oxide 41 is patterned by an anisotropic etching in an area 42 in which later a trench is to be etched. Then, as indicated at B, the trench 5 is etched, that is by anisotropic etching, into the silicon, wherein the remaining oxide 41 acts as an etch protection for the remaining part of the semiconductor. As it is indicated at C, then a further layer 43 is applied which is also an oxide layer and covers both the oxide 41 and also the trench side walls and the trench bottom in the trench 5. Thus, the second layer 43 is at least applied to the trench side walls in the embodiment. If this layer is also applied to the trench bottom, it is, as it is indicated at D, at least removed again there, i.e. at the trench bottom 44, but remains at the trench side walls. This may be achieved by an anisotropic etching (spacer etching). At E, the semiconductor material is then isotropically etched, wherein the etching is prevented at the semiconductor surface and at the trench side walls by the first (on top of the semiconductor) and the second layer (at the trench side walls). By this, the spreading 30 results, as no directed, i.e. anisotropic, but an isotropic etching is performed, wherein the isotropic etching distinguishes itself by the fact that the etching rates are less or not at all directional. By further processes, the MOSFET or IGBT is completed. In one embodiment, the layers 41 and 43 are removed. On top of that, a gate oxide 6 is then generated such that in the case of the IGBT or the power MOSFET without an integrated field plate it evenly covers the trench bottom, i.e. the spreading, and also the trench neck, i.e. the top area. With the trench power MOSFET having an integrated field plate, however, the gate oxide is generated only after introducing and etching back the oxide of the field plate only at the side wall of the top trench neck area. Subsequently, the trench 5 covered with the oxide 6 is at least partially filled with polysilicon to complete the gate electrode 7. In one embodiment, also another conductive material may be filled into the trench.

It is to be noted, that the doping areas as they are indicated in FIG. 1a are not indicated in FIG. 3 in the pictures A, B, C, D, E and are only schematically illustrated in dashed lines in picture F.

In one embodiment, it is to be noted, that some embodiments start with a semiconductor substrate in picture A which already has the necessary doping profiles. In one embodiment, doping profiles, if they are arranged close to the surface of the substrate, i.e. in the area of the layers 3 and 4, may, for example, also be introduced later, for example by implantation and diffusion or by a deep implantation.

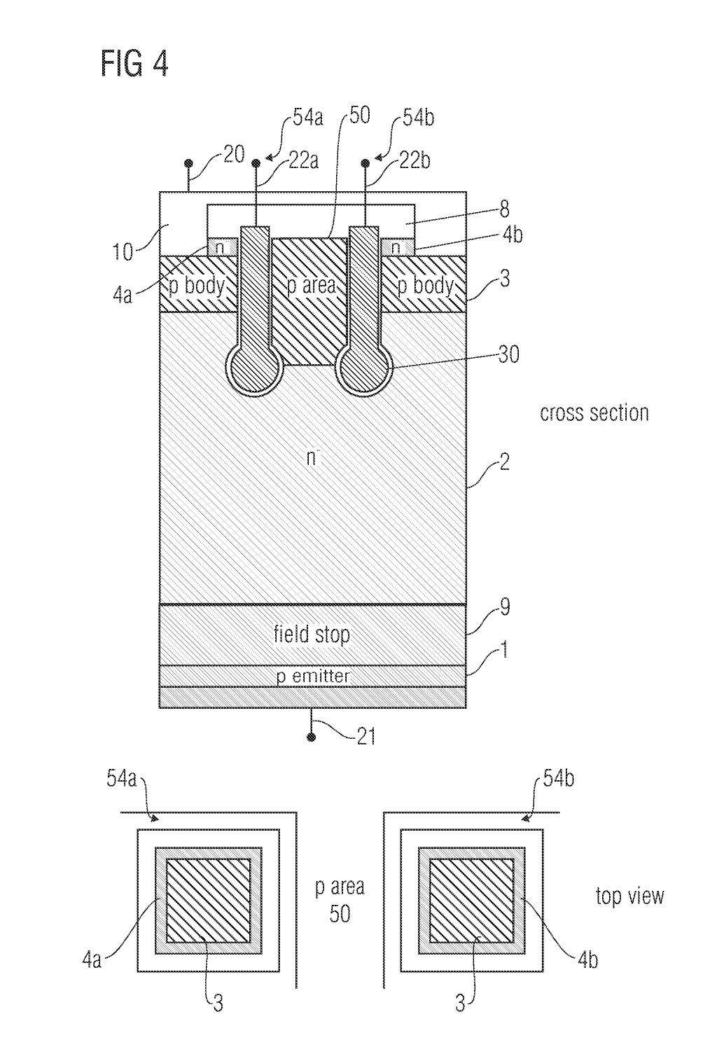

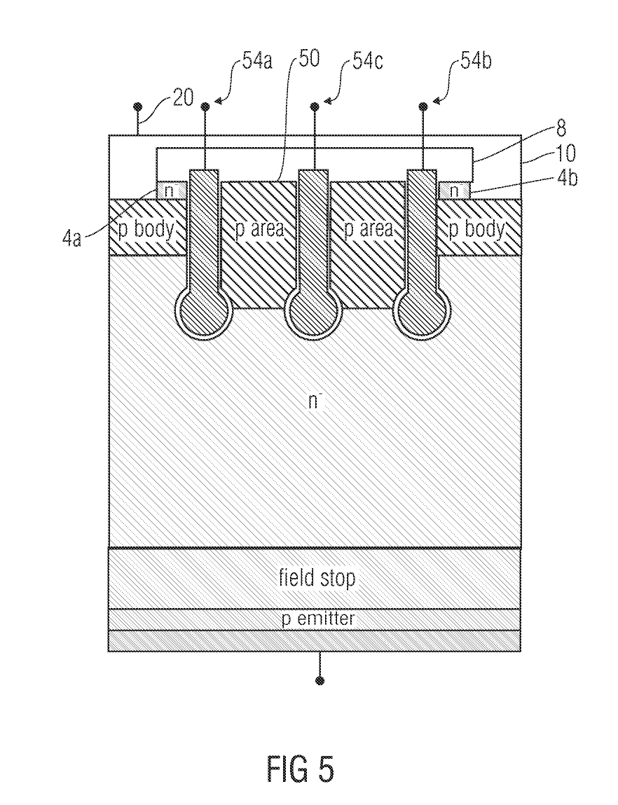

FIG. 4 illustrates a further embodiment with square cells set at a distance. Here (and also in the strip structure), as it is in one embodiment indicated in FIG. 5, between the two trenches 54A, 54B e.g., a further trench 54C may be provided. The electrodes of those further trenches may be connected to the gate potential or to the source potential. Further, in the embodiments illustrated in FIG. 4 and FIG. 5, in the area in between the cells a p-area 50 is provided, wherein such a p-area 50 may either be freely floating or may be on a source or emitter potential, respectively. The metallization 10 also indicated in FIG. 1A connects the two emitter areas 4A, 4B so that the IGBT indicated in FIG. 4 thus includes two transistor cells connected in parallel. In FIG. 5, the two emitter areas 4A, 4B are also short-circuited by a metallization 10. The p-areas here act, if they are freely floating, as further additional barriers, wherein it is to be noted that the middle trench 54C in FIG. 5 is, so to speak, a dummy trench, as it has no emitter areas 4A or 4B, as the same are only provided for the two outer trenches.

It is to be noted that both in FIG. 4 and also in FIG. 5 the oxide 8 which is arranged across the first semiconductor areas 4A, 4B also extends across the additional p-areas 50, so that the p-areas from the metallization 10 to the source contacting are insulated via the source or emitter contact 20, respectively.

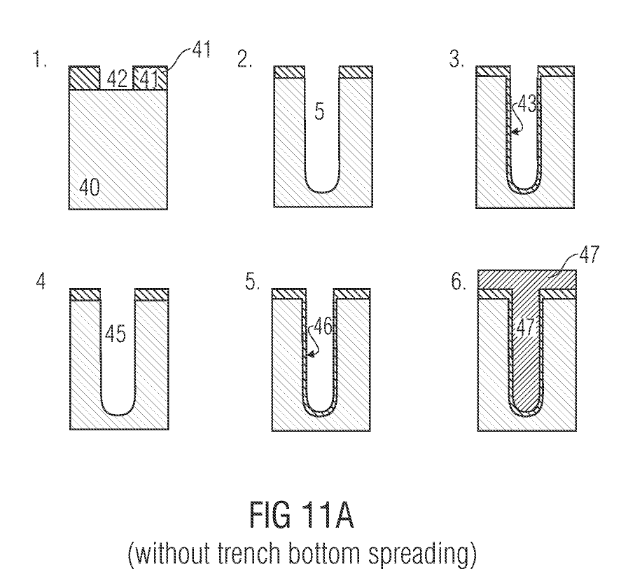

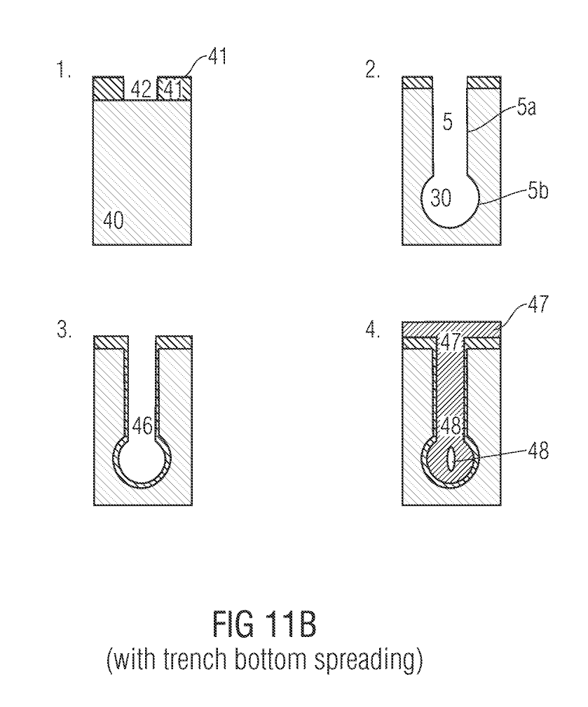

In one implementation, the material in the trench, which is, for example, polysilicon, may completely or only partially fill the spreading area 30, wherein in one embodiment the spreading area may also include a cavity 48 (FIG. 11B) inside.

It is further to be noted that the pn-transition may be between the p-area 3 and the low-doped n-area in the region of the spreading or above the spreading. In FIG. 1a the pn-transition is between the layers 2 and 3 above the spreading, while in variants B, C, D the pn-transition is in the area of the spreading, as it may be seen from the light/dark edge of the doping distribution designated by 37 in variant D. It is further to be noted that the spreading does not necessarily have to be at the bottom of the trench. If the spreading is, for example, in the middle of the trench, such that the trench continues into layer 2 after the spreading, this also presents a hole barrier as long as an area of the trench which has the greater dimension (d2 in FIG. 1a) is outside the p-body area 3 and in the low-doped layer 2.

FIG. 1C illustrates the semiconductor device having two adjacently arranged trenches which represents the top section of an IGBT or an MOSFET. The trenches indicated there surround an active cell and are spaced apart from each other by mass d3 or d4, respectively, as indicated in FIG. 1C.

In one embodiment, the trenches have a width d2 in the area of the spreading which is at least 1.5 times the width of the trench above the spreading, i.e. the dimension d1.

Further, the area between two trenches above the spreading designated by d3 in FIG. 1C should at least be 1.5 times as wide as the narrowest point in the area of the spreading, wherein this dimension is designated by d4 in FIG. 1C. Still more advantageous is a factor between d3 and d4 which is 2, wherein also already values greater than 1.1. are advantageous.

Depending on the implementation, the structure may be formed from strip-shaped cells or polygonal, in one embodiment square cells. Here, the left trench 54A in FIG. 4 is implemented such that it forms a square trench in top view which surrounds the left edge of the illustration of FIG. 4. Such a structure is illustrated at the bottom of the top view of FIG. 4.

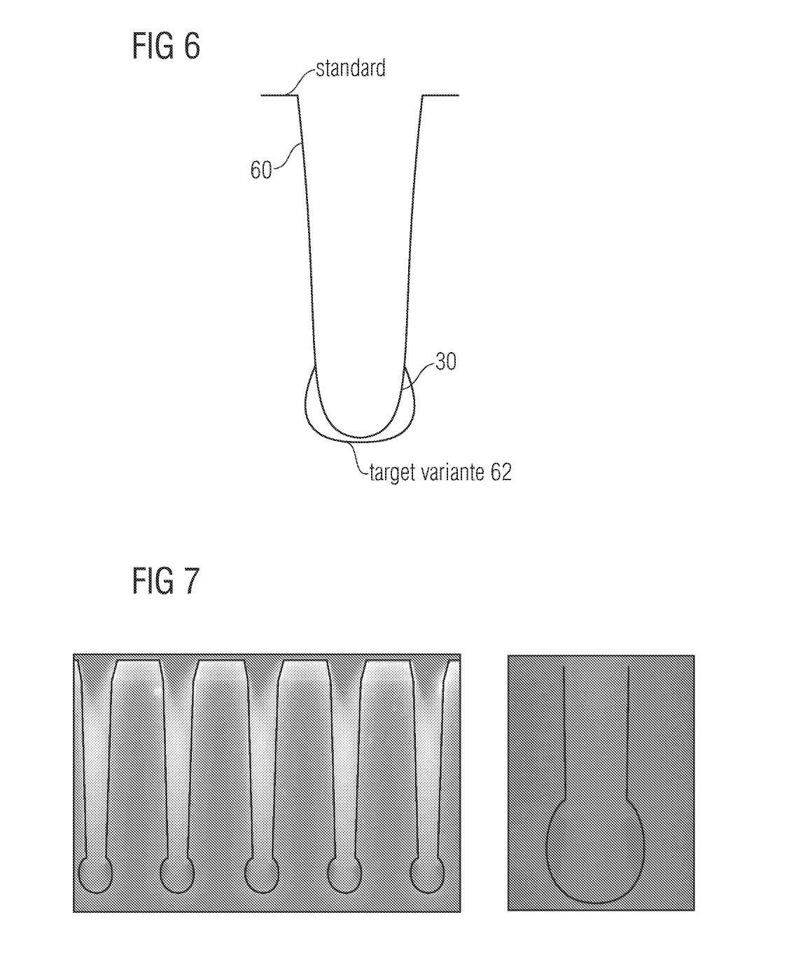

FIG. 6 initially illustrates a standard variant 60, i.e. a trench which extends from top to bottom in a semiconductor material and which includes a tapering from top to bottom. The target variant is further indicated at 62, wherein the target variant should not change anything at the trench in its top thin or “neck” area, but only lead to a spreading 30 in the trench bottom area. By a change in the process of plasma etching at the end of the otherwise anisotropic trench etching to a basically isotropic etching characteristic, the side wall passivation in the bottom part of the trench is broken and the trench bottom is spread into a kind of “drop shape”. The strongly isotropic etching at the end of the trench etching is further to round off the trench bottom better as compared to the purely anisotropically conducted process, so that an otherwise necessitated rounding oxide process may be omitted. The rounding oxide process is an oven process in which a thin thermal oxide is generated at the trench bottom and at the trench side walls and a rounding in one embodiment of the bottom trench edges and the trench bottom is achieved. Subsequently, the rounding oxide may be removed again. This process, however, causes an increase of the overall trench width, wherein this increase directly affects the minimum raster of the trenches which may be achieved. The inventive process thus does not only save an oxidation and etching process for the rounding oxide, but also leads to a direct reduction of the trench width by, e.g., approx. 75 nm. These 75 nm per trench may be directly integrated into the cell raster, wherein it may be advantageous to make the raster as small as possible. With a raster of, e.g., 1.25 μm, by the reduction of the trench width by 75 nm already a significant reduction of the cell raster may be achieved. With reference to the overall device, this leads to a reduction of the ON resistance, as an increased number of electrically active transistor cells may be placed in a cell field and thus, due to the increased channel width, the current carrying capacity is increased and the resistance is decreased.

FIG. 7 illustrates electron microscope recordings of several neighboring trenches having a clear spreading at the trench bottom and were realized with the above-described variation of the inventive etching process.

Further, a more favorable field distribution is achieved at the trench bottom by setting a greater radius of curvature of the trench bottom by the spreading. In one embodiment with power MOSFETs this leads to a higher breakdown voltage and thus enables, with field plate trench transistors, a reduction of the FOX thickness in the trench, in connection with a further reduction of the raster and the ON resistance.

On the left in FIG. 8 the simulation of the non-conductive state for an MOSFET having a standard trench is illustrated which is tapered from top to bottom under a certain angle. On the other hand, on the right in FIG. 8 a trench according to the invention is illustrated including the spreading 30 at the trench bottom. It may be seen that the equipotential lines which are characteristic for the respective field course are substantially more concentrated and strongly curved at the trench bottom of the standard trench. By the already described spreading 30 the equipotential lines at the bottom of the inventive trench experience an increase of the radius of curvature at the trench bottom and are pressed further outwards. Thus, a reduction of the electric field strength in this area results which directly correlates with the radius of curvature of the equipotential lines. Further, by the spreading 30 the location of the breakthrough (breakdown) of the MOS power transistor realized in the trench design is clamped better at the trench bottom and a shift of the breakthrough with normal operation conditions into the area between two trenches is excluded, so that the parasitic bipolar transistor of source, body and drain cannot switch on. This is the precondition for a high robustness of the device in the avalanche operation.

FIG. 8 illustrates, as already discussed, the results of an accompanying simulation. It may be seen that the greater radius of curvature at the trench bottom influences the distribution and the course of the field lines and presses the same further outwards. By the change of geometry undertaken at the trench bottom also the breakdown voltage increases, as indicated in FIG. 9. Also advantageous is the resulting reduction of the field strength in the field oxide by, e.g., approximately 10% (FIG. 10), which means more security regarding the degradation and lifetime of the device.

FIG. 11A illustrates a method for the manufacturing of a field plate trench MOSFET without spreading. On the other hand, in FIG. 11B the inventive manufacturing method for a trench bottom spreading is illustrated. By the introduction of the new trench geometry, not only an improvement of the electric performance of the device (breakdown voltage, ON resistance) is achieved, but simultaneously a reduction of the necessary process results.

In the following, with reference to FIGS. 11A and 11B the two manufacturing methods with spreading and without spreading are illustrated in more detail.

In FIG. 11A, first of all a hard mask 41 is applied and patterned to define a later trench etching. In one embodiment, the hard mask includes an opening 42 in which the trench is finally to be formed. In the partial image designated by No. 2 of FIG. 11A, a trench etching took place, that is an anisotropic trench etching in other to produce the trench 5. In the process stage illustrated in the third partial image, a rounding process was performed to apply a thin oxide which lines the whole trench. This thin oxide 43 is also referred to as ROX or round oxide, respectively. The fourth partial image illustrates the result, i.e. a trench 45 without a round oxide when an isotropic round oxide removal has been performed regarding the structure illustrated in the third partial image using dry etching.

The fifth partial image illustrates the state after a field oxide (FOX) 46 has been introduced. After the introduction of the field oxide, the trench is finally filled with a conductive material which is designated by 47 in the sixth partial image. It is to be noted, that by the isotropic round oxide etching the lateral dimension of the trench 5 was made passable, i.e. enlarged from top to bottom. This leads to an enlarged pitch, i.e. to a greater trench distance, when a plurality of trenches illustrated in FIG. 11A are introduced into a semiconductor substrate, e.g., for the purposes of an IGBT or a power MOSFET.

FIG. 11B illustrates a manufacturing sequence according to one embodiment, wherein again first a hard mask 41 is applied and patterned to generate an opening 42 in the hard mask which defines the later trench. The result of this patterning is illustrated in the partial image 1 and is similar to the partial image 1 of FIG. 1A.

The partial image 2 illustrates the result of a trench etching which is first an anisotropic trench etching which then changes into an isotropic etching characteristic towards the end, which leads to the trench bottom spreading 30 being maintained. Hereupon, a field oxide 46 is applied which covers both the top part 5a and also the bottom part 5b of the trench. The result after introducing the field oxide (FOX) 46 is illustrated in the third partial image of FIG. 11B. Hereupon, the trench is filled with a conductive material 47. This filling may lead to a cavity 48, depending on the implementation, which results from the fact that the filling only takes place in a uniform thickness from the trench side wall. This cavity is uncritical, however, as it influences neither the hole jam in the IGBT nor the field strength distribution in the MOSFET negatively.

By the procedure illustrated in FIG. 11B, the number of manufacturing processes is reduced by two processes, i.e. by the process of introducing the round oxide 43 of FIG. 11A (partial image 3) and the process of removing the round oxide (partial image 4) in FIG. 11A.

Simultaneously, by changing the etching characteristic to an isotropic etching characteristic to generate the structure according to the partial image 2 of FIG. 11B, automatically a well-rounded trench bottom is obtained, which is important so that no local field strength superelevations result at the gate or in the gate oxide, respectively, which would develop into breakdown zones which would substantially reduce the breakdown voltage of the overall transistor.

In the method illustrated in FIG. 11B, thus two advantages are achieved simultaneously, i.e. on the one hand the number of processes is reduced by no round oxide being necessitated and by changing to an isotropic etching characteristic at the bottom of the trench, wherein this isotropic etching characteristic at the same time leads, however, to the fact that the trench is optimally rounded to let no field strength peaks result in the oxide. Apart from that it is further guaranteed that no trench spreading takes place in the top area 5A of the trench as it is, however, directly obtained by an isotropic removal of the round oxide. This leads to the already illustrated reduced pitch in the trench dimensioning, which leads to a better semiconductor device.

In the following, the processes are explained in more detail which take place when the structure illustrated in the partial image 2 in FIG. 11B is produced. First of all, a completely anisotropic etching is performed using an etching gas. In this anisotropic etching two things take place. On the one hand, at the trench bottom silicon material is removed by etching, while at the trench side walls a passivation layer forms. This passivation layer becomes thicker the longer a trench side wall is subjected to the anisotropic etching process. In other words, at the trench bottom where the etching gas so to speak perpendicularly impacts the semiconductor material the passivation layer is not present, while at the trench side wall in the proximity of the trench bottom the passivation layer is thin and gradually increases towards the trench end at the top side of the semiconductor. This increasing thickness results from the fact that the passivation layer becomes thicker the longer a trench side wall is subjected to the anisotropically etching gas.

If the etching gas is changed by changing it to an isotropic etching gas either step by step or in one or two short processes, the etching now acts isotropically. For the trench bottom this means that the semiconductor material is simply etched further. At the trench side wall directly at the trench bottom the passivation layer generated by the anisotropic etching is still very thin and is attacked and removed by the isotropically etching gas. At a certain location of the trench side wall, however, the passivation layer which was generated by the anisotropic etching is already so thick that it is not broken through by the isotropic etching any more. Thus, a relatively sharp transition of the top area 5a into the bottom area 5b is generated. Further, it is thus guaranteed, that the trench width is not changed, as the trench side wall in the top area 5a is protected by a sufficiently thick passivation layer and not attacked by the anisotropic etching.

While embodiments of the invention have been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device, comprising:
a first semiconductor area and a second semiconductor area;
a semiconductor body area between the first semiconductor area and the second semiconductor area, wherein a doping characteristic of the semiconductor body area is inverse to a doping characteristic of the first semiconductor area and the second semiconductor area;
a trench which extends adjacent to the semiconductor body area from the semiconductor surface at least up to the second semiconductor area; and
a gate arranged in the trench and separated from the semiconductor body by an insulation layer, wherein the trench comprises a top trench portion which extends from the semiconductor surface at least to a depth which is greater than a depth of the first semiconductor area, wherein the trench further comprises a bottom trench portion which extends subsequently to the top trench portion at least up to the second semiconductor area, and wherein the top trench portion comprises a first lateral dimension and the bottom trench portion comprises a second lateral dimension which is greater than the first lateral dimension.

2. The semiconductor device of claim 1, comprising being formed as an MOS field-effect transistor, wherein the first semiconductor area is a source area, wherein the second semiconductor area is a drain area and wherein the semiconductor body area is implemented such that in the semiconductor body area a conductive channel may be formed if a corresponding voltage is applied to the gate, and wherein the trench extends through the semiconductor body area and into the source area or the drain area, wherein the top trench portion in the semiconductor body area comprises the first lateral dimension and the bottom trench portion in the area which extends into the source area or the drain area comprises the second lateral dimension.

3. The semiconductor device of claim 1, comprising being implemented as a bipolar transistor comprising an insulated gate, wherein the first semiconductor area comprises an emitter, wherein the semiconductor body area represents a top base area which is adjacent to the emitter, wherein the second semiconductor area represents a bottom base area which is adjacent to the top base area, wherein the trench extends through the top base area and into the bottom base area, wherein the top trench portion in the top base area comprises the first lateral dimension and the bottom trench portion in the bottom base area comprises the second lateral dimension.

4. The semiconductor device of claim 1, comprising wherein the doping characteristic in the semiconductor body area is a p-characteristic and the doping characteristic in the first semiconductor area and in the second semiconductor area is an n-characteristic.

5. The semiconductor device of claim 1, comprising wherein a doping concentration in the second semiconductor area is smaller than a doping concentration in the first semiconductor area.

6. The semiconductor device of claim 1, comprising wherein a doping concentration in the second semiconductor area is smaller than a doping concentration in the semiconductor body area.

7. The semiconductor device of claim 1, comprising wherein the trench is dimensioned so that the second dimension is greater at least by the factor 1.1 than the first dimension.

8. The semiconductor device of claim 1, comprising wherein the trench extends from a first side of a semiconductor substrate into the substrate in the direction towards a second side, and wherein the area comprising the greater dimension represents a spreading which is arranged at least partially outside the semiconductor body area.

9. The semiconductor device of claim 1, wherein the top trench portion comprises a trench neck comprising the first dimension and the bottom trench portion comprises a trench bottom comprising the second dimension, wherein the spreading is located at the trench bottom.

10. The semiconductor device of claim 1, comprising wherein the trench is insulated from a surrounding semiconductor material by an oxide layer and comprises polysilicon or metal as a conductive filling;
wherein the top portion of the trench comprises a conductive filling insulated from the semiconductor body area which is conductively connected to a control electrode of the semiconductor device, and wherein the bottom portion further comprises a further conductive filling which is insulated from the conductive filling of the top portion by an insulation layer; and
wherein the further conductive filling is implemented as a field plate and is implemented floatingly or connected such that its potential may be brought to a potential of the first semiconductor area.

11. The semiconductor device of claim 1, comprising wherein the bottom trench portion is drop-shaped; and
wherein the first semiconductor area is conductively connected to an emitter or source terminal.

12. The semiconductor device of claim 1, comprising wherein two adjacent trenches surrounding an active cell are spaced apart from each other so that a distance between the trenches in an area in which the spreading is not located is more than 1.1 times as large as a distance at the narrowest point in the area of the spreading.

13. The semiconductor device comprising:
a further trench next to the trench, wherein between the trenches an area with a doping is located which comprises the same doping characteristic as the semiconductor body area.

14. The semiconductor device of claim 13, comprising wherein the area is floating or is connected such that it is on the same potential as the first semiconductor area.

15. The semiconductor device of claim 13, further comprising a third trench between the one trench and the further trench.

16. The semiconductor device of claim 15, comprising wherein the third trench includes an electrode connected to the same potential as the electrodes in the one trench and in the further trench or to an emitter potential.

17. A method for manufacturing a semiconductor device, comprising:
generating a trench extending into a semiconductor substrate which comprises a spreading in the semiconductor substrate so that the trench is broader in an area of the spreading than in an area which is adjacent to the spreading;
generating an insulation layer in the spreading; and
filling at least a part of the spreading of the trench with a conductive material.

18. The method of claim 17, wherein the semiconductor device is an MOS field-effect transistor, wherein the method further comprises:
generating a source terminal contacting a first semiconductor area and a drain terminal contacting a second semiconductor area, wherein the trench extends through a semiconductor body area and into the second semiconductor area, and wherein at least a part of the spreading is arranged outside the semiconductor body area and in the second semiconductor area.

19. The method of claim 17, wherein the semiconductor device is a bipolar transistor comprising an insulated gate, further comprising:
generating an emitter terminal contacting a first semiconductor area and a collector terminal contacting, via a collector semiconductor layer and, as applicable, a field stop layer, a second semiconductor area which comprises a bottom base area adjacent to a semiconductor body area representing a top base area, wherein the trench extends through the semiconductor body area and into the bottom base area of the second semiconductor area, and wherein at least one part of the spreading is arranged outside the semiconductor body area and in the bottom base area.

20. The method of claim 17, wherein generating the trench comprises an anisotropic etching of the semiconductor substrate to generate the trench and an isotropic etching of the trench to obtain the spreading.

21. The method of claim 20, comprising applying after the anisotropic etching a layer masking the etching to a trench side wall.

22. The method of claim 21, comprising applying the masking layer both to a trench side wall and also to a trench bottom, wherein before the isotropic etching the masking layer is removed at the trench bottom.

23. The method of claim 17, further comprising applying a masking layer before etching the trench, applying a second masking layer after etching the trench and, after generating the spreading, removing the first and the second layer.

24. The method of claim 17, wherein generating the trench comprising the spreading is performed in an etching process which is controlled such that first an anisotropic etching takes place and that then, after a certain time, a control of the etching process takes place so that a less anisotropic and more isotropic etching takes place to generate the spreading.

25. The method of claim 24, comprising wherein the etching process is a dry etching process, wherein a portion of an anisotropically etching gas is gradually reduced with an etching atmosphere to gradually achieve a more isotropic etching characteristic.
